(19) United States
(12) Patent Application Publication
(10) Pub. No.: US 2026/0223389 A1
(43) Pub. Date: Jul. 30, 2026

(54) SEMICONDUCTOR DEVICE

(71) Applicant: RENESAS ELECTRONICS CORPORATION, Tokyo (JP)

(72) Inventors: Tomohiro IMAI, Tokyo (JP); Atsushi SAKAI, Tokyo (JP)

(21) Appl. No.: 19/422,795

(22) Filed: Dec. 17, 2025

(30) Foreign Application Priority Data
Jan. 29, 2025 (JP) 2025-013316

(51) Int. Cl. H10D 30/65; H10D 62/10; H10D 62/17; H10D 64/00

(52) U.S. Cl. CPC H10D 30/65; H10D 62/107; H10D 62/393; H10D 64/111

(57) ABSTRACT

A semiconductor device includes a first semiconductor layer and a second semiconductor layer formed in a semiconductor substrate, a first buried region formed in the first semiconductor layer, a drain region, a drift region, a source region, and a body region formed in the second semiconductor layer, a back-gate region formed in the body region, a gate electrode formed on an upper surface of the semiconductor substrate, and a second buried region formed in the second semiconductor layer and disposed between the first buried region and the body region. A side surface of the second buried region is located between the gate electrode and the drain region in plan view. The second buried region is connected to the body region.

### CROSS-REFERENCE TO RELATED APPLICATIONS

The disclosure of Japanese Patent Application No. 2025-013316 filed on January 29, 2025 including the specification, drawings and abstract is incorporated herein by reference in its entirety.

### BACKGROUND

The present disclosure relates to a semiconductor device, and more particularly to a semiconductor device including a high-breakdown-voltage Metal-Oxide-Semiconductor Field Effect Transistor (MOSFET).

There are disclosed techniques listed below.

[Patent Document 1] Japanese Unexamined Patent Application Publication No. 2020-129597

Patent Document 1 discloses a structure of a semiconductor device for improving the on-state breakdown voltage of a Laterally-Diffused Metal-Oxide Semiconductor Field Effect Transistor (LDMOSFET).

The semiconductor device of Patent Document 1 includes an n-type well region, a p-type well region, a p-type source region, a p-type drain region, and an n-type body contact region in a p-type epitaxial layer. In addition, the semiconductor device includes an insulating isolation film formed in the vicinity of the drain region, and includes a buried region for element isolation and a sinker region.

### SUMMARY

In the semiconductor device of Patent Document 1, an electric field is concentrated in the insulating isolation film, and carriers having high energy (hot carriers) are generated by impact ionization. These hot carriers are injected into the insulating isolation film (hot carrier injection (HCI)), causing deterioration of the device.

In addition, in the semiconductor device of Patent Document 1, the breakdown voltage of the element is determined by the expansion of the depletion layer in the vertical direction, that is, in the depth direction. As a result, the current becomes difficult to flow, the on-resistance of the semiconductor device increases, and it is not possible to design a high-breakdown-voltage element.

Accordingly, a semiconductor device that achieves higher breakdown voltage and further improvement in HCI reliability is expected. Other objects and novel features will become apparent from the description of the present specification and the accompanying drawings.

According to one embodiment, the semiconductor device of the present disclosure includes a second buried region disposed between a buried region and a body region. Accordingly, concentration of an electric field on an insulating isolation film can be suppressed, and higher breakdown voltage and improved HCI reliability of the semiconductor device can be achieved.

The present disclosure makes it possible to provide a semiconductor device that achieves high breakdown voltage and improved HCI reliability.

### BRIEF DESCRIPTION OF THE DRAWINGS

FIG. 1 is a cross-sectional view of a semiconductor device of a first embodiment.

FIG. 2A is a plan view of the semiconductor device of the first embodiment.

FIG. 2B is a plan view of the semiconductor device of the first embodiment.

FIG. 2C is a plan view of the semiconductor device of the first embodiment.

FIG. 2D is a plan view of the semiconductor device of the first embodiment.

FIG. 3 is a contour diagram of electric-field intensity obtained by simulation of a first comparative example.

FIG. 4 is a contour diagram of electric-field intensity obtained by simulation of a second comparative example.

FIG. 5 is a contour diagram of electric-field intensity obtained by simulation of a semiconductor device of the first embodiment.

FIG. 6 is a cross-sectional view of a first modification of a semiconductor device of a second embodiment.

FIG. 7 is a cross-sectional view of a second modification of a semiconductor device of the second embodiment.

FIG. 8 is a cross-sectional view of a third modification of a semiconductor device of the second embodiment.

FIG. 9 is a cross-sectional view of a fourth modification of a semiconductor device of the second embodiment.

FIG. 10 is a cross-sectional view of a fifth modification of a semiconductor device of the second embodiment.

FIG. 11 is a cross-sectional view of a semiconductor device of a third embodiment.

FIG. 12 is a plan view of the semiconductor device of the third embodiment.

FIG. 13 is a cross-sectional view of the semiconductor device of the third embodiment.

FIG. 14 is a flowchart illustrating a method of manufacturing a semiconductor device of the first embodiment.

FIG. 15 is a cross-sectional view of the semiconductor device in a method of manufacturing in the third embodiment.

FIG. 16 is a cross-sectional view of the semiconductor device in the method of manufacturing in the third embodiment.

FIG. 17 is a cross-sectional view of the semiconductor device in the method of manufacturing in the third embodiment.

FIG. 18 is a cross-sectional view of the semiconductor device in the method of manufacturing in the third embodiment.

FIG. 19 is a cross-sectional view of the semiconductor device in the method of manufacturing in the third embodiment.

FIG. 20 is a cross-sectional view of the semiconductor device in the method of manufacturing in the third embodiment.

FIG. 21 is a cross-sectional view of the semiconductor device in the method of manufacturing in the third embodiment.

FIG. 22 is a cross-sectional view of the semiconductor device in the method of manufacturing in the third embodiment.

FIG. 23 is a cross-sectional view of the semiconductor device in the method of manufacturing in the third embodiment.

FIG. 24 is a cross-sectional view of the semiconductor device in the method of manufacturing in the third embodiment.

FIG. 25 is a cross-sectional view of the semiconductor device in the method of manufacturing in the third embodiment.

FIG. 26 is a cross-sectional view of the semiconductor device in the method of manufacturing in the third embodiment.

### DETAILED DESCRIPTION

Hereinafter, embodiments of the present disclosure will be described in detail with reference to the drawings. In the specification and drawings, the same or corresponding components are denoted by the same reference numerals, and redundant descriptions will be omitted. In the drawings, components may be omitted or simplified for convenience of description. At least part of the respective embodiments may be combined with each other as desired.

In the semiconductor device of the present disclosure, the conductivity type (p-type or n-type) of a semiconductor substrate, semiconductor regions, diffusion regions, transistors, and the like, may be reversed. When one of the n-type and the p-type is defined as a first conductivity type and the other is defined as a second conductivity type, the first conductivity type may be defined as the p-type and the second conductivity type may be defined as the n-type, or conversely, the first conductivity type may be defined as the n-type and the second conductivity type may be defined as the p-type. In the following embodiments, for convenience, the first conductivity type will be described as the p-type, and the second conductivity type will be described as the n-type.

The impurity concentration of component included in the semiconductor device of the present disclosure refers to a peak value in a measured region of the component. When the impurity concentrations of two components are compared and are described as “substantially the same,” this does not mean that they must be completely identical. Even if the impurity concentrations of the two components differ due to manufacturing variations, the impurity concentrations of the two components are regarded as being the same as long as the set values of the impurity concentrations of the two components are the same.

In the present disclosure, the state of “being connected” includes a state of “being electrically connected”.

### FIRST EMBODIMENT

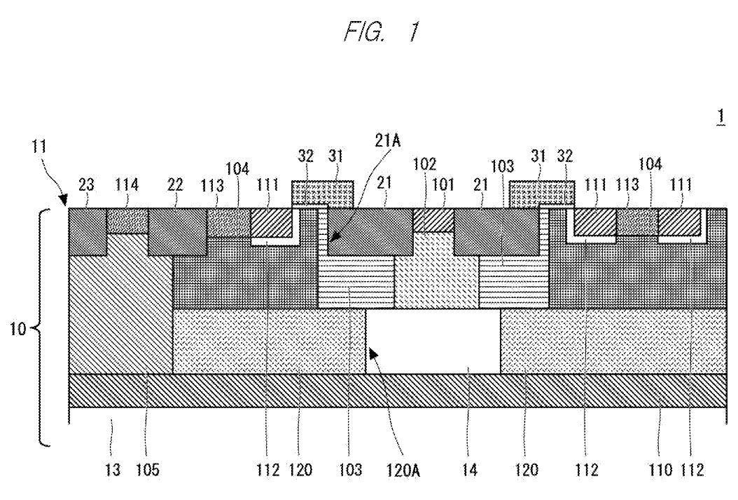

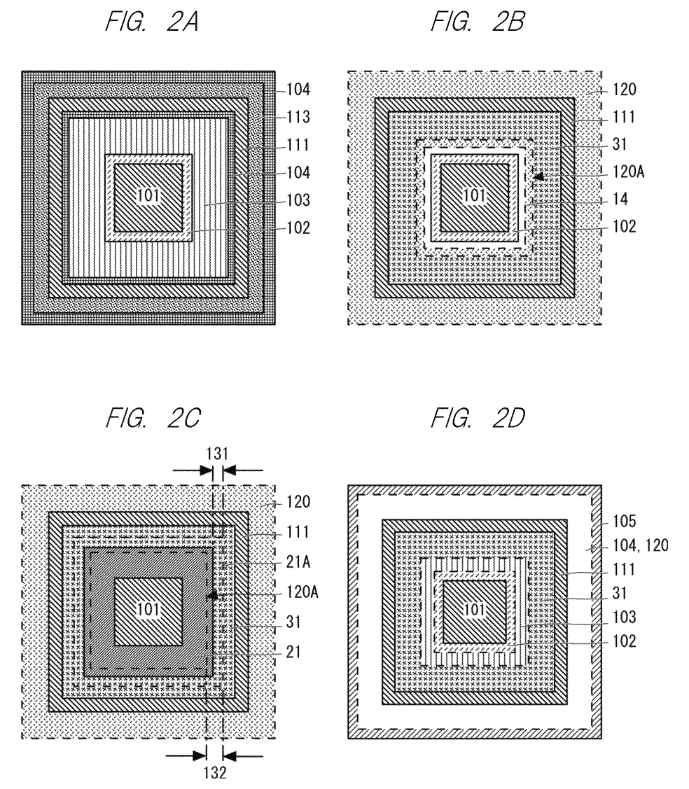

FIG. 1 is a cross-sectional view of a semiconductor device 1 of the present disclosure, and FIGS. 2A to 2D are plan views of the semiconductor device 1. Examples of the semiconductor device 1 include a semiconductor chip including a Metal-Oxide-Semiconductor Field Effect Transistor (MOSFET), a semiconductor wafer, and a package in which these are mounted.

The semiconductor device 1 includes a semiconductor substrate 10 having the first conductivity type, which is p-type, and includes a plurality of regions formed in the semiconductor substrate 10. The semiconductor substrate 10 has an upper surface 11 and a lower surface (not illustrated) opposite to the upper surface 11. Hereinafter, unless otherwise noted, components included in the semiconductor device 1 illustrated in FIG. 1 are formed at the upper surface 11 of the semiconductor substrate 10.

The semiconductor substrate 10 includes a substrate body and a first semiconductor layer 13 and a second semiconductor layer 14, which are epitaxial layers formed on the substrate body. Each of the first semiconductor layer 13 and the second semiconductor layer 14 has the first conductivity type, which is p-type.

A first buried region 110 having the second conductivity type, which is n-type, opposite to the first conductivity type, is formed in the first semiconductor layer 13. The first buried region 110 functions as an element isolation layer.

A first drain region 101 and a second drain region 102, each having the first conductivity type, which is p-type, are formed in the second semiconductor layer 14. The first drain region 101 is disposed at the upper surface 11 of the semiconductor substrate 10, and the second drain region 102 is disposed under the first drain region 101. The second drain region 102 is a p-type well region and covers a corner portion of a first insulating region 21 described later. The second drain region 102 has a function of relaxing an electric field at the corner portion of the first insulating region 21 during an on-state and improving the on-state breakdown voltage of the semiconductor device. The impurity concentration of the second drain region 102 is, for example, lower than the impurity concentration of the first drain region 101.

Hereinafter, unless otherwise noted, the first drain region 101 and the second drain region 102 are collectively referred to as a “drain region”.

A drift region 103 having the first conductivity type, which is p-type, is formed in the second semiconductor layer 14 and, as illustrated in FIG. 2A, is disposed so as to surround the first drain region 101 in plan view of the semiconductor device 1. The impurity concentration of the drift region 103 is, for example, lower than the impurity concentration of the second drain region 102.

The plan view illustrated in FIG. 2A illustrates only the first drain region 101, the second drain region 102, the drift region 103, a body region 104, a source region 111, and a back-gate region 113 (described later), in order to avoid complexity.

The source region 111 having the first conductivity type, which is p-type, is formed in the second semiconductor layer 14. The source region 111 is disposed at the upper surface 11 of the semiconductor substrate 10 and is disposed apart from the drain region. A lightly doped region 112 is formed under the source region 111.

The body region 104 having the second conductivity type, which is n-type, is formed in the second semiconductor layer 14 and, as illustrated in FIG. 2A, is disposed so as to enclose the source region 111 in plan view.

The back-gate region 113 having the second conductivity type, which is n-type, is formed in the body region 104 and is disposed at the upper surface 11 of the semiconductor substrate 10.

A gate electrode 31 is formed on the upper surface 11 of the semiconductor substrate 10 so as to face the drift region 103 and the body region 104 via a gate insulating film 32.

A second buried region 120 having the second conductivity type, which is n-type, is formed in the second semiconductor layer 14 and is disposed between the first buried region 110 and the body region 104. As illustrated in FIG. 2B, a side surface 120A of the second buried region 120 is located between the gate electrode 31 and the drain region in plan view. The side surface 120A of the second buried region 120 may be located, in plan view, between the body region 104 and the drain region, or between a side surface 21A of the first insulating region 21 and the drain region.

The plan view illustrated in FIG. 2B describes only the first drain region 101, the second drain region 102, the second semiconductor layer 14, the gate electrode 31, the source region 111, and the second buried region 120, in order to avoid complexity. Dotted lines in FIG. 2B indicate the second drain region 102, the second semiconductor layer 14, the side surface 120A of the second buried region 120, and an end portion of the second buried region 120, which are not visible from the uppermost surface.

Each of the drift region 103 and the body region 104 is located over the second buried region 120, and the second buried region 120 is connected to the body region 104.

The second buried region 120 is disposed apart from the drain region via the second semiconductor layer 14 facing the side surface 120A of the second buried region 120. In addition, as illustrated in FIG. 2B, the second buried region 120 surrounds the drain region in plan view.

The second buried region 120 is connected to the back-gate region 113 via the body region 104. Accordingly, the second buried region 120 has an effect of absorbing hot carriers generated by impact ionization. Further, the second buried region 120 has an effect of relaxing concentration of an electric field in a channel region formed under the gate electrode 31. In addition, as described later, by locating the side surface 120A of the second buried region 120 between the gate electrode 31 and the drain region, between the body region 104 and the drain region, or between the side surface 21A of the first insulating region 21 and the drain region, concentration of an electric field at the corner portion or a bottom portion of the first insulating region 21 can be suppressed.

The first insulating region 21 is formed in the drift region 103 and, as illustrated in FIG. 2C, surrounds the drain region, particularly the first drain region 101, in plan view.

The plan view illustrated in FIG. 2C describes only the first drain region 101, the first insulating region 21, the gate electrode 31, the source region 111, and the second buried region 120, in order to avoid complexity. Dotted line in FIG. 2C illustrate the side surface 120A of the second buried region 120, the side surface 21A of the first insulating region 21, and the end portion of the second buried region 120, which are not visible from the uppermost surface.

As illustrated in FIG. 2C, the gate electrode 31 has a first offset region 131 that overlaps the first insulating region 21 in plan view. As illustrated in a plan view of FIG. 2C, the second buried region 120 has a second offset region 132 that overlaps the first insulating region 21. In a direction from the source region 111 toward the drain region (a gate-length direction), a length of the first offset region 131 differs from a length of the second offset region 132. Preferably, the length of the first offset region 131 is smaller than the length of the second offset region 132.

The material of the gate electrode 31 is metal or conductive polysilicon.

A sinker region 105 having the second conductivity type, which is n-type, is formed in the second semiconductor layer 14. As illustrated in a plan view in FIG. 2D, the sinker region 105 surrounds the drain region, the drift region 103, the gate electrode 31, the source region 111, the body region 104, and the second drain region 102.

The plan view illustrated in FIG. 2D describes only the first drain region 101, the second drain region 102, the drift region 103, the gate electrode 31, the source region 111, the body region 104, the second buried region 120, and the sinker region 105, in order to avoid complexity. In the plan view illustrated in FIG. 2D, hatchings of the body region 104 and the second buried region 120 are omitted because the body region 104 and the second buried region 120 overlap each other. Dotted lines in FIG. 2D illustrate the second drain region 102, the drift region 103, the body region 104, and the end portion of the second buried region 120, which are not visible from the uppermost surface.

In the plan views illustrated in FIGS. 2A to 2D, a planar shape of the drain region is a square, and the source region 111 and the second buried region 120 surround the drain region. The present disclosure is not limited to the plan views illustrated in FIGS. 2A to 2D, and in plan view, the drain region and the source region 111 may each have a stripe shape. In that case, in plan view, the source region 111 does not necessarily surround the drain region, and the drain region may be disposed between two source regions 111. Further, in plan view, the second buried region 120 does not necessarily surround the drain region, and the second buried region 120 only needs to be disposed at least between the drain region and the sinker region 105.

In the configuration example of the semiconductor device of the first embodiment illustrated in FIG. 1, the second buried region 120 is in contact with the first buried region 110 and is electrically connected to the sinker region 105 via the first buried region 110.

A high-concentration impurity region 114 having the second conductivity type, which is n-type, is formed in the second semiconductor layer 14 and is located over the sinker region 105. The impurity concentration of the high-concentration impurity region 114 is, for example, higher than the impurity concentration of the sinker region 105.

A second insulating region 22 is formed between the source region 111 and the high-concentration impurity region 114 and surrounds the source region 111 in plan view (not illustrated).

A third insulating region 23 is formed in the sinker region 105 and surrounds the high-concentration impurity region 114 in plan view (not illustrated).

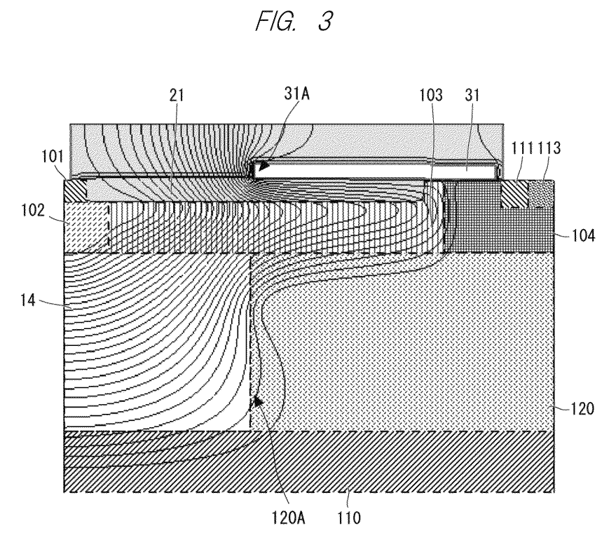

As described above, in the configuration example of the semiconductor device in FIG. 1, the second buried region 120 is formed, and in plan view, the side surface 120A of the second buried region 120 is located, for example, between the gate electrode 31 and the drain region. Effects of such a structure will be described with reference to FIGS. 3 to 5.

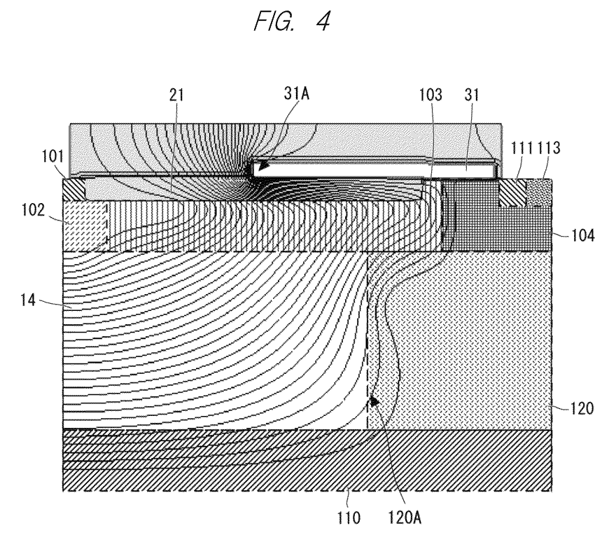

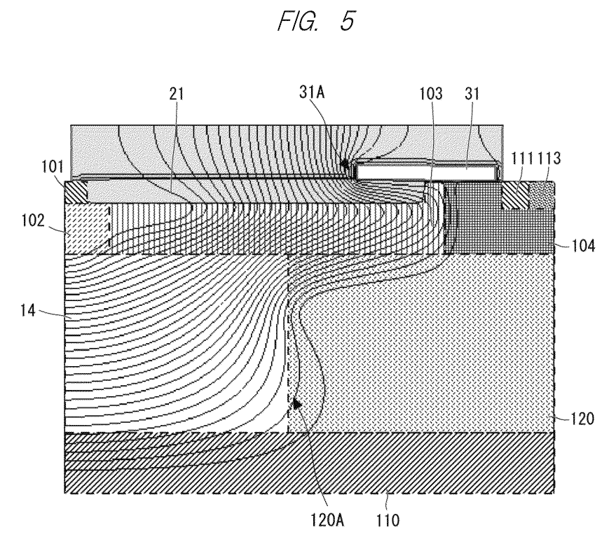

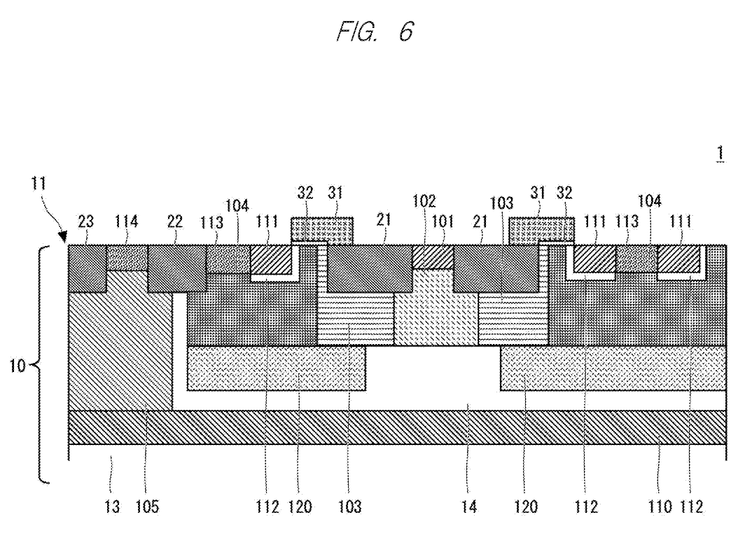

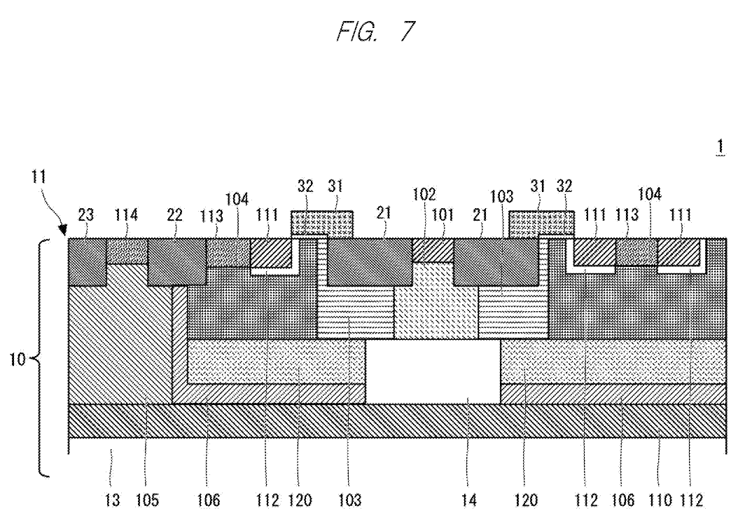

FIG. 3 illustrates a contour diagram of electric-field intensity obtained by Technology CAD (TCAD) simulation of the first comparative example. FIG. 4 illustrates a contour diagram of electric-field intensity obtained by TCAD simulation of the first comparative example. FIG. 5 illustrates a contour diagram of electric-field intensity obtained by TCAD simulation of Example 1 of the present disclosure. The simulation was performed under conditions in which a gate voltage was set to −1.75 V and a drain voltage was set to −51 V. In the contour diagrams, the first drain region 101, the second drain region 102, the drift region 103, the body region 104, the second semiconductor layer 14, the first insulating region 21, the gate electrode 31, the source region 111, the back-gate region 113, the first buried region 110, and the second buried region 120 are illustrated in superimposition.

In the first comparative example illustrated in FIG. 3, a position of a side surface 31A of the gate electrode 31 and a position of the side surface 120A of the second buried region 120 are the same in plan view. That is, the length of the first offset region 131 and the length of the second offset region 132 illustrated in FIG. 2C are the same as each other. In this case, an electric field is concentrated at the bottom portion of the first insulating region 21, and deterioration due to Hot Carrier Injection (HCI) occurs.

In the first comparative example illustrated in FIG. 4, a position of the side surface 31A of the gate electrode 31 is the same as in the first comparative example, and a position of the side surface 120A of the second buried region 120 in plan view is located between the side surface 31A of the gate electrode 31 and the body region 104. That is, the length of the first offset region 131 is greater than the length of the second offset region 132 illustrated in FIG. 2C. In the first comparative example, concentration of an electric field generated at the bottom portion of the first insulating region 21 in the first comparative example is relaxed. On the other hand, an effect of absorbing hot carriers by the second buried region 120 becomes smaller, and deterioration due to HCI occurs.

In Example 1 illustrated in FIG. 5, in plan view, the side surface 31A of the gate electrode 31 is located between the gate electrode 31 and the drain region. That is, the length of the first offset region 131 is smaller than the length of the second offset region 132 illustrated in FIG. 2C. Accordingly, similar to the first comparative example, concentration of an electric field at the bottom portion of the first insulating region 21 is relaxed. Further, due to the effect of absorbing hot carriers by the second buried region 120, deterioration due to HCI is smaller than in the first comparative example and the first comparative example.

As described above, the second buried region 120 can absorb hot carriers generated by impact ionization, relax concentration of an electric field in the channel region, and suppress concentration of an electric field at a corner portion or a bottom portion of the first insulating region. Accordingly, the semiconductor device according to the first embodiment can achieve higher breakdown voltage and improved HCI reliability.

### SECOND EMBODIMENT

In the second embodiment, modifications of the semiconductor device 1 of the first embodiment will be described. Note that the first embodiment and the second embodiment may be combined with each other as appropriate, and repeated descriptions of components similar to those in the configuration example of the first embodiment are omitted.

### FIRST MODIFICATION

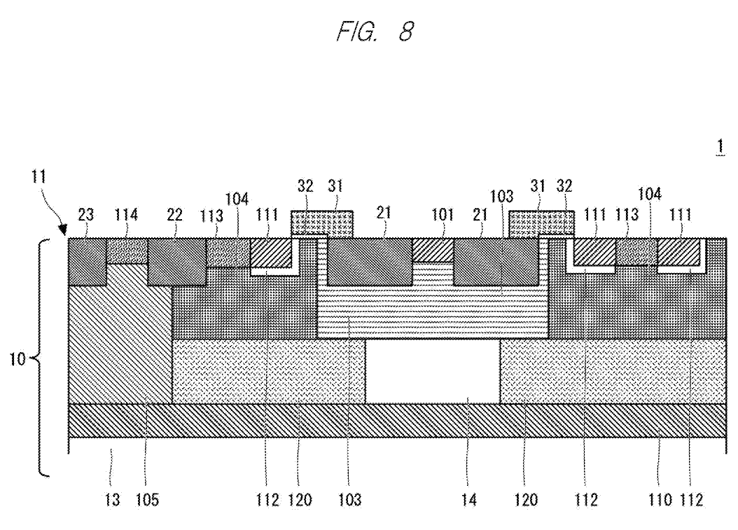

The semiconductor device 1 illustrated in FIG. 6 is configured such that the first buried region 110 and the second buried region 120 are disposed apart from each other via the second semiconductor layer 14, that is, the source region 111 and the first buried region 110 are not short-circuited. By a portion of the second semiconductor layer 14 being interposed between the body region 104 and the second buried region 120 and the sinker region 105, punch-through between the body region 104 and the second buried region 120, and the sinker region 105 can be suppressed. In addition, the semiconductor device 1 of a first modification can be formed with the same number of masks as the semiconductor device 1 of the first embodiment.

### SECOND MODIFICATION

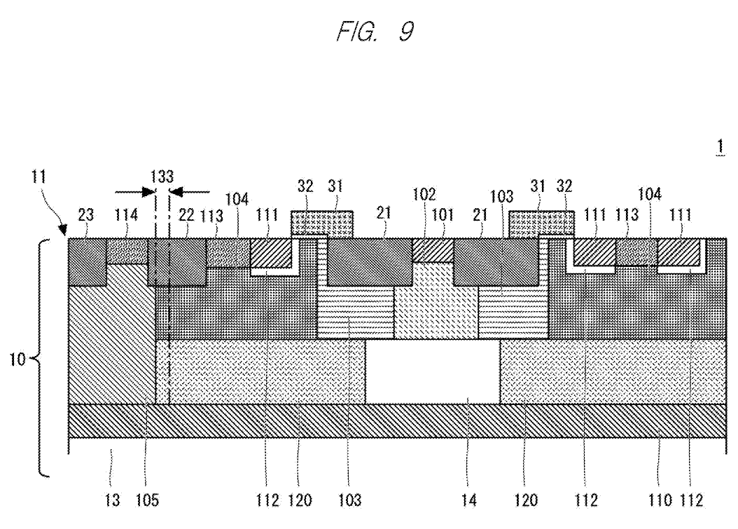

FIG. 7 is a modification of the first modification illustrated in FIG. 6. In the semiconductor device 1 illustrated in FIG. 7, the first buried region 110 and the second buried region 120 are disposed apart from each other via a semiconductor region 106 having the first conductivity type, which is p-type, formed in the second semiconductor layer 14. An impurity concentration of the semiconductor region 106 is, for example, higher than an impurity concentration of the second semiconductor layer 14. The semiconductor device 1 of a second modification can prevent punch-through between the body region 104 and the second buried region 120, and the sinker region 105 and the first buried region 110, without changing the device size.

### THIRD MODIFICATION

The semiconductor device 1 illustrated in FIG. 8 does not include the second drain region 102 illustrated in the semiconductor device 1 of the first embodiment. The second drain region 102 is a p-type well region and has a function of improving the on-state breakdown voltage of the semiconductor device. On the other hand, when a high on-state breakdown voltage is not required for the semiconductor device, the second drain region 102 does not need to be formed, and the number of masks can be reduced and the device size can be further reduced compared with the semiconductor device 1 of the first embodiment.

### FOURTH MODIFICATION

The semiconductor device 1 illustrated in FIG. 9 is configured such that the body region 104 and the second buried region 120 partially or entirely overlap the sinker region 105. Compared with the semiconductor device 1 of the first embodiment, the sinker region 105 of the semiconductor device 1 illustrated in FIG. 9 overlaps by a length of a third offset region 133. Accordingly, resistance between the first buried region 110 and the sinker region 105 is reduced, and operation of a parasitic PNP bipolar transistor can be prevented.

### FIFTH MODIFICATION

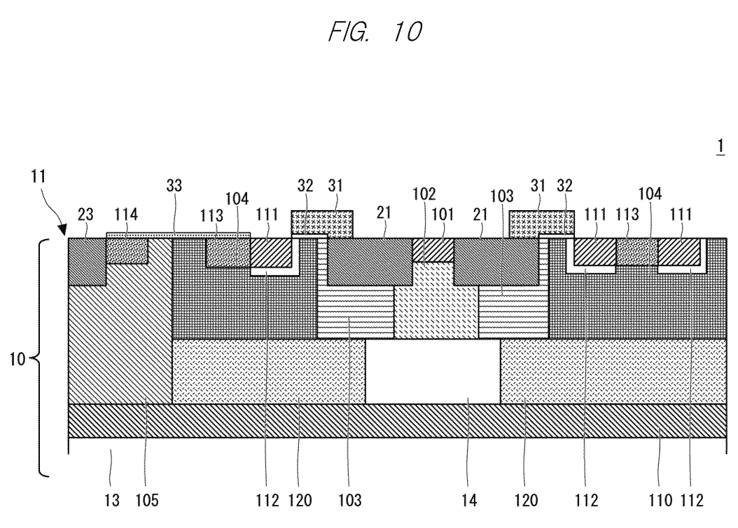

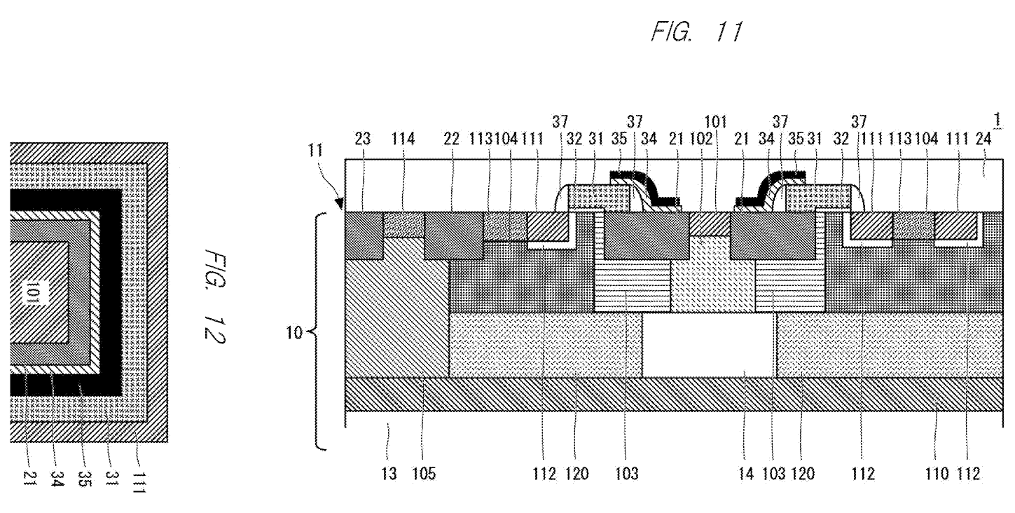

The semiconductor device 1 illustrated in FIG. 10 is configured such that the source region 111 and the first buried region 110 are short-circuited, and a shared contact plug 33 is disposed on the back-gate region 113 and on the sinker region 105. Accordingly, the second insulating region 22 between the source region 111 and the sinker region 105 can be omitted, and the device size can be reduced.

### THIRD EMBODIMENT

In the third embodiment, additional structures of the semiconductor device 1 of the first embodiment and the second embodiment, and a method of manufacturing the semiconductor device 1, will be described. Note that the first embodiment through the third embodiment may be combined with each other as appropriate, and repeated descriptions of components similar to those in the configuration example of the first embodiment are omitted.

The semiconductor device 1 illustrated in FIG. 11 further includes a field-plate electrode 35. The field-plate electrode 35 is formed on the first insulating region 21 and, as illustrated in FIG. 12, is disposed such that a portion of the field-plate electrode 35 overlaps the gate electrode 31 via an insulating layer 34 and a sidewall spacer 37 in plan view. The plan view illustrated in FIG. 12 describes only the first drain region 101, the first insulating region 21, the insulating layer 34, the field-plate electrode 35, the gate electrode 31, and the source region 111.

The semiconductor device 1 illustrated in FIG. 11 further includes an interlayer insulating film 24 formed on the semiconductor substrate 10 so as to cover the gate electrode 31 and the field-plate electrode 35.

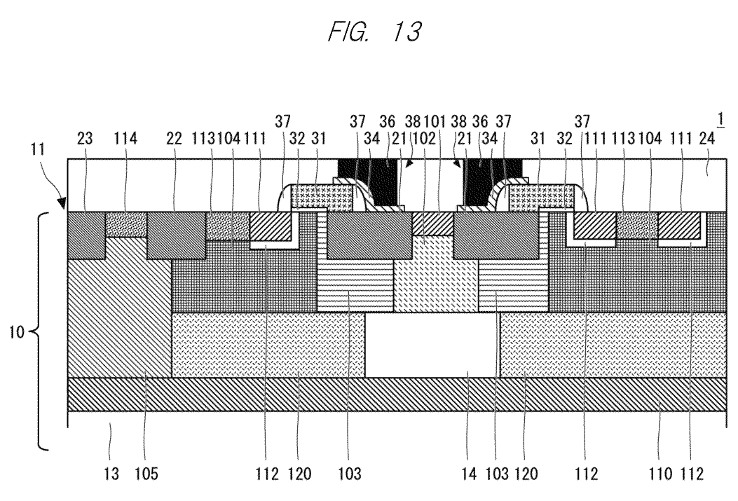

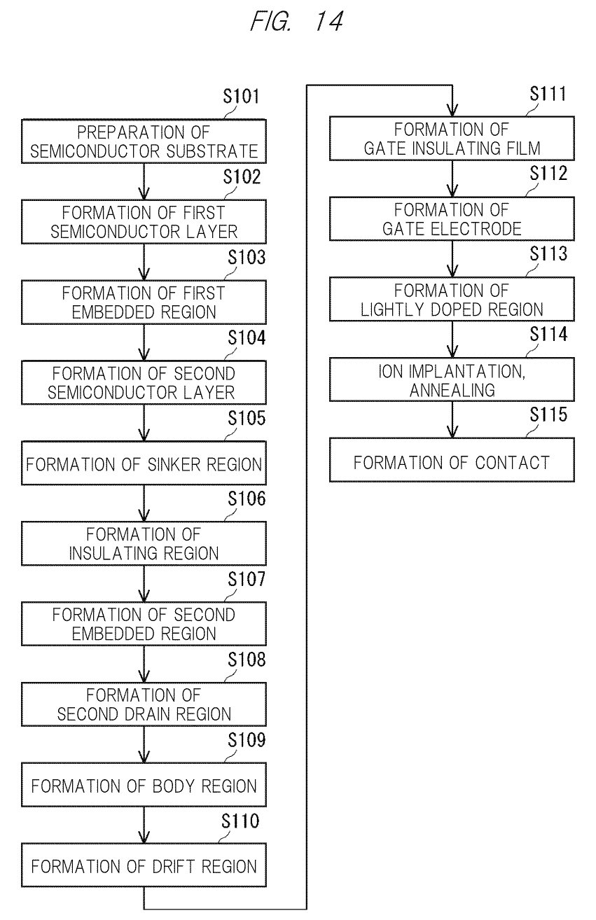

The semiconductor device 1 illustrated in FIG. 13 further includes a contact field-plate electrode 36. The semiconductor device 1 includes the interlayer insulating film 24 formed on the semiconductor substrate 10, and a through-hole 38 formed in the interlayer insulating film 24 and located on the first insulating region 21. The contact field-plate electrode 36 is formed in the through-hole 38.

Hereinafter, a method of manufacturing the semiconductor device 1 will be described. FIG. 14 is a flowchart illustrating the method of manufacturing the semiconductor device.

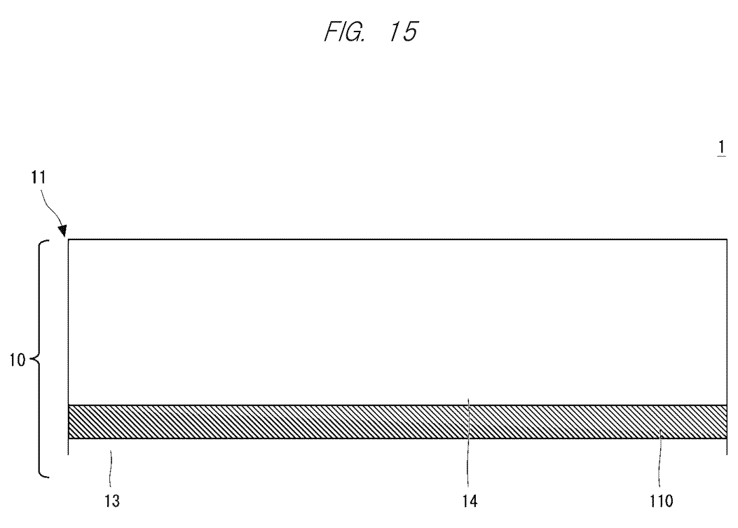

As illustrated in FIG. 15, a semiconductor substrate 10 having the first conductivity type, which is p-type, and having a substrate body, a first semiconductor layer 13, a second semiconductor layer 14, and a first buried region 110, is prepared (S101). Specifically, first, the substrate body is prepared. Next, the first semiconductor layer 13 is formed on the substrate body by an epitaxial growth method (S102).

Next, impurity ions having the second conductivity type, which is n-type, are implanted into the first semiconductor layer 13, and an annealing process is performed on the first semiconductor layer 13, thereby forming the first buried region 110 at an upper surface of the first semiconductor layer 13 (S103).

After forming the first buried region 110, the second semiconductor layer 14 is formed on the first semiconductor layer 13 by an epitaxial growth method (S104). Note that the first buried region 110 may be formed so as to extend across the first semiconductor layer 13 and the second semiconductor layer 14 due to diffusion of impurities caused by heat treatment for forming the second semiconductor layer 14 and heat treatment in subsequent processes.

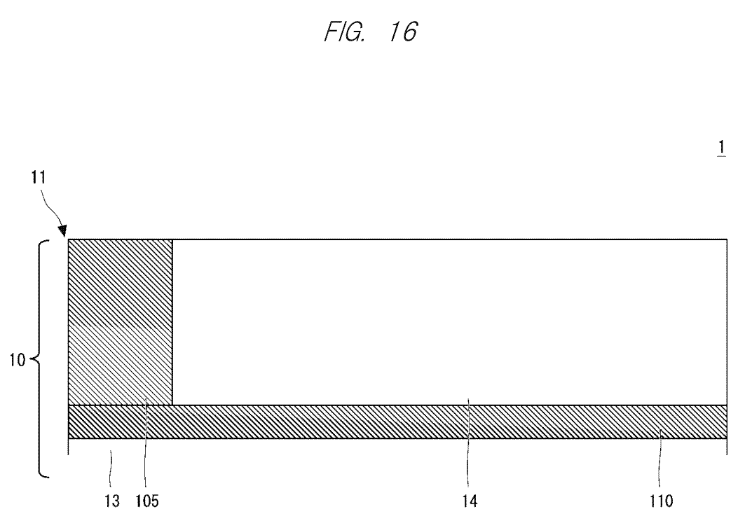

After forming the second semiconductor layer 14, as illustrated in FIG. 16, ions having the second conductivity type, which is n-type, are implanted into the second semiconductor layer 14 from the upper surface 11 of the semiconductor substrate 10, and an annealing process is performed, thereby forming the sinker region 105 (S105). The ion implantation is performed using, for example, a photoresist as a mask.

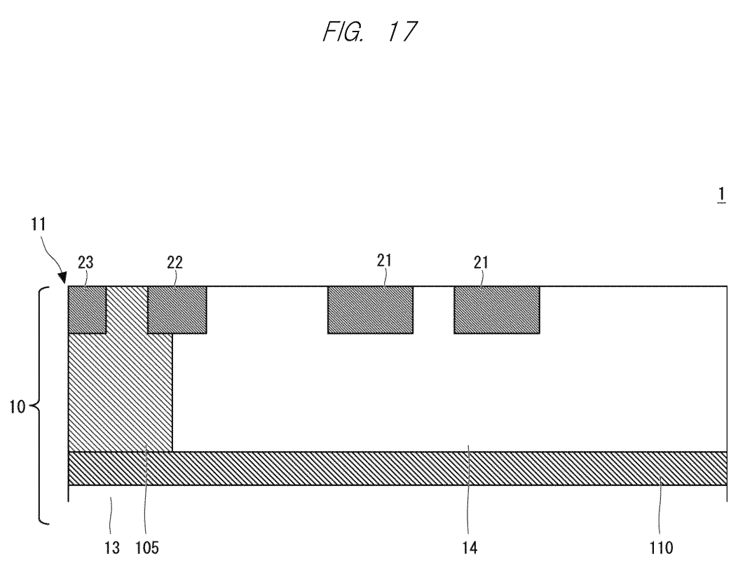

After forming the sinker region 105, as illustrated in FIG. 17, the first insulating region 21, the second insulating region 22, and the third insulating region 23 are formed (S106). First, a trench is formed in the upper surface 11 of the semiconductor substrate 10. The trench is formed by, for example, anisotropic dry etching such as reactive ion etching (RIE). Next, a material constituting the first insulating region 21, the second insulating region 22, and the third insulating region 23 is embedded into the trench. The embedding of the material is performed by, for example, chemical vapor deposition (CVD). Thereafter, the material formed outside the trench is removed by, for example, chemical mechanical polishing (CMP), thereby forming the first insulating region 21, the second insulating region 22, and the third insulating region 23.

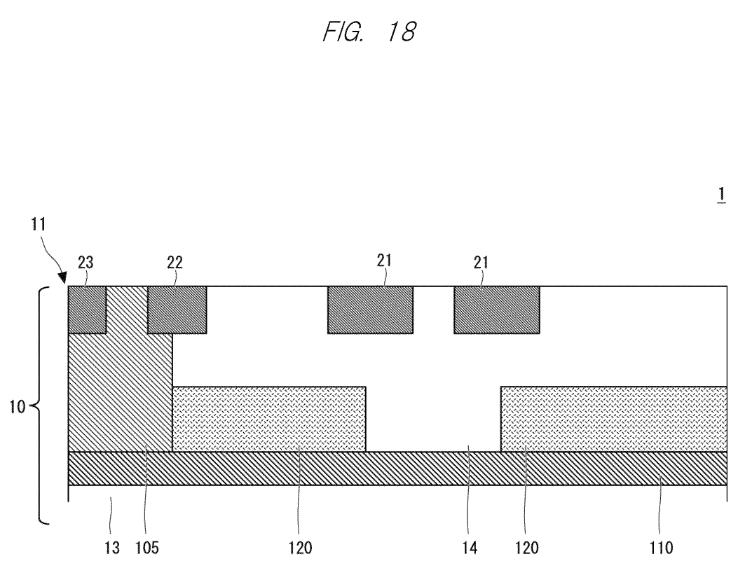

After forming the first insulating region 21, the second insulating region 22, and the third insulating region 23, as illustrated in FIG. 18, the second buried region 120 is formed (S107). The second buried region 120 is formed by implanting ions having the second conductivity type, which is n-type, into the second semiconductor layer 14 from the upper surface 11 of the semiconductor substrate 10 and performing an annealing process. The ion implantation is performed using, for example, a photoresist as a mask.

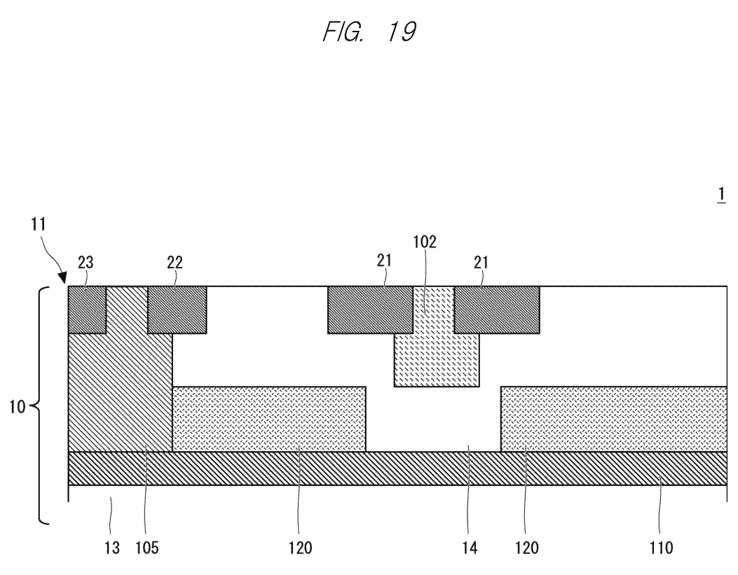

After forming the second buried region 120, as illustrated in FIG. 19, ions having the first conductivity type, which is p-type, are implanted into the second semiconductor layer 14 from the upper surface 11 of the semiconductor substrate 10, and an annealing process is performed, thereby forming the second drain region 102 (S108). The ion implantation is performed using, for example, a photoresist as a mask.

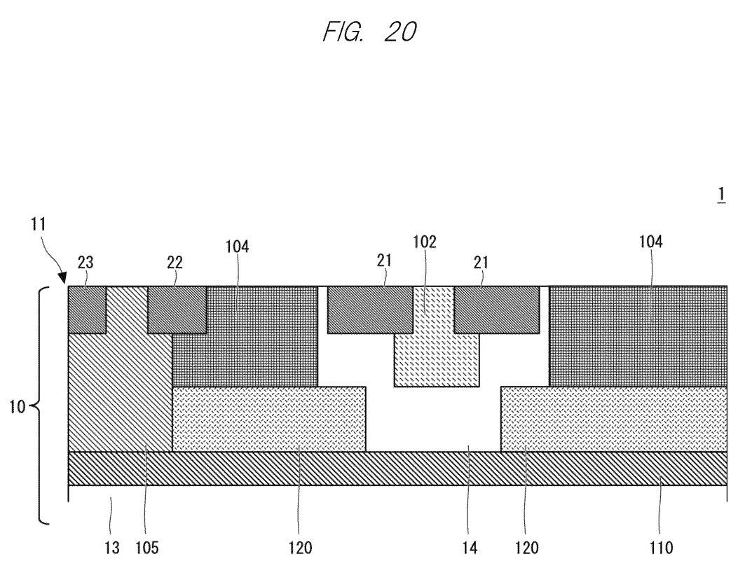

After forming the second drain region 102, as illustrated in FIG. 20, ions having the second conductivity type, which is n-type, are implanted into the second semiconductor layer 14 from the upper surface 11 of the semiconductor substrate 10, and an annealing process is performed, thereby forming the body region 104 (S109). The ion implantation is performed using, for example, a photoresist as a mask.

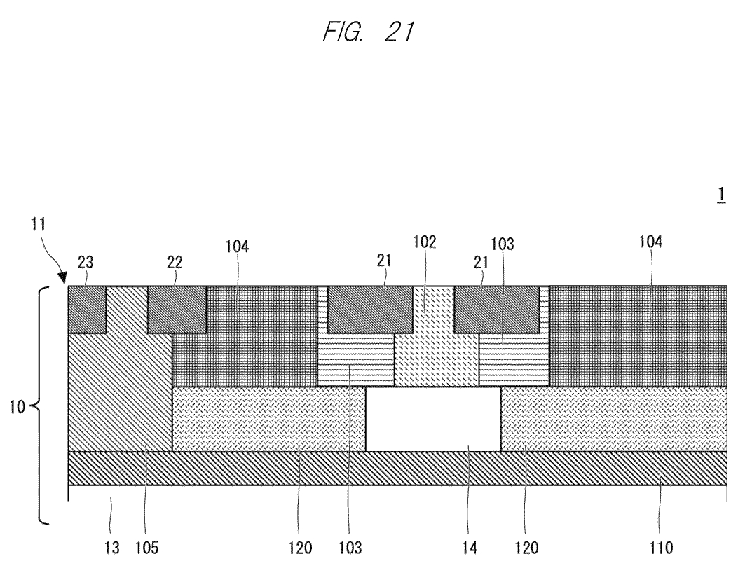

After forming the body region 104, as illustrated in FIG. 21, ions having the first conductivity type, which is p-type, are implanted into the second semiconductor layer 14 from the upper surface 11 of the semiconductor substrate 10, and an annealing process is performed, thereby forming the drift region 103 (S110). The ion implantation is performed using, for example, a photoresist as a mask.

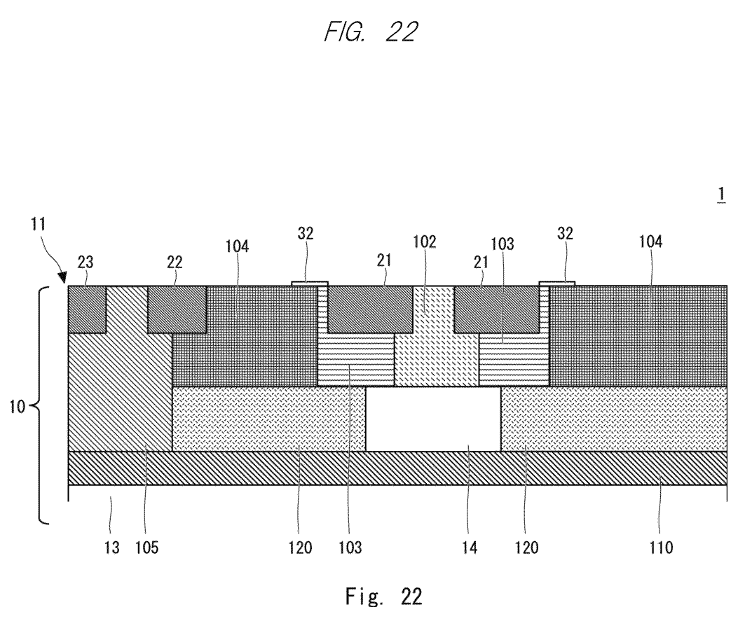

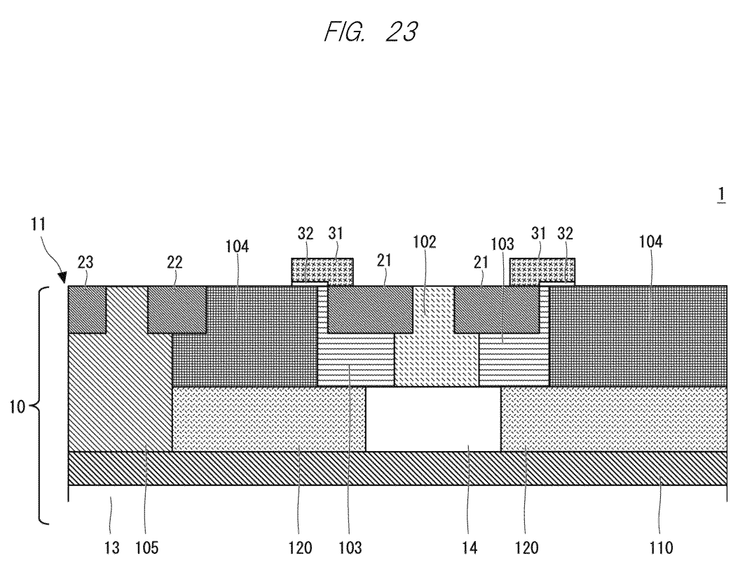

After forming the drift region 103, as illustrated in FIG. 22, a gate insulating film 32 is formed on the upper surface 11 of the semiconductor substrate 10 by, for example, a thermal oxidation method (S111).

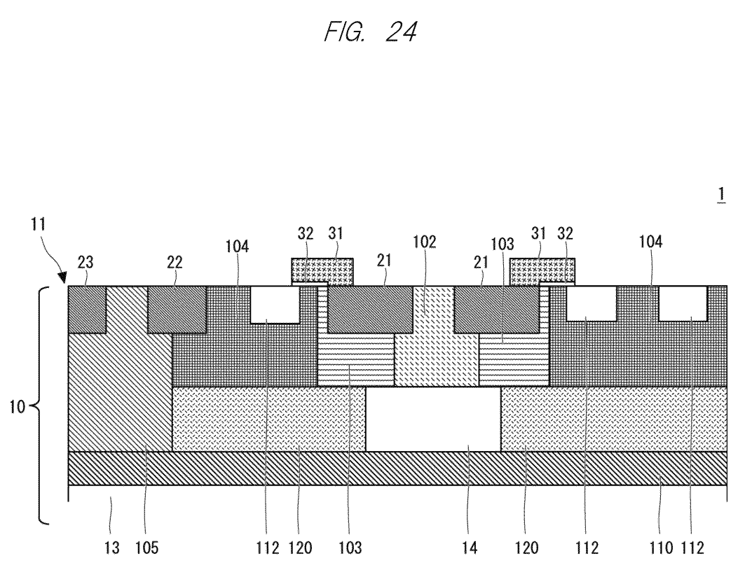

After forming the gate insulating film 32, as illustrated in FIG. 23, a gate electrode 31 is formed (S112). First, a material constituting the gate electrode 31 is deposited on the upper surface 11 of the semiconductor substrate 10 by, for example, chemical vapor deposition (CVD). Next, the deposited material is patterned by dry etching using a photoresist formed by photolithography, thereby forming the gate electrode 31.

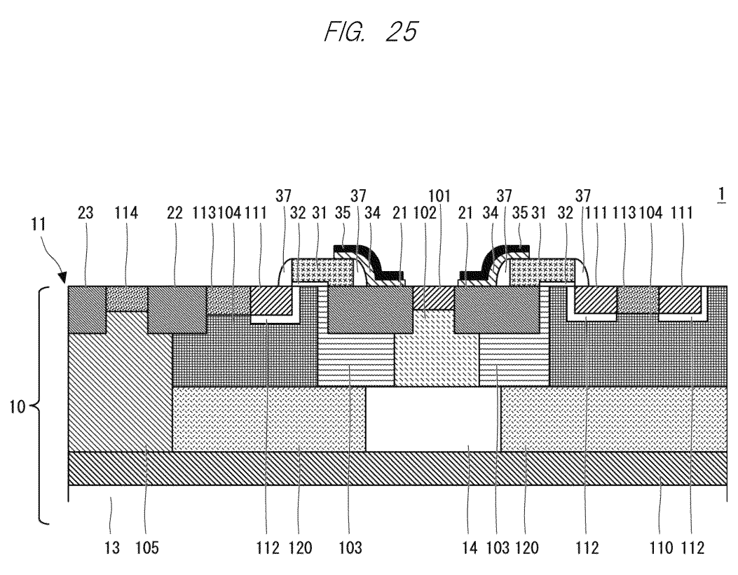

After forming the gate electrode 31, as illustrated in FIG. 24, ions having the first conductivity type, which is p-type, are implanted into the second semiconductor layer 14 from the upper surface 11 of the semiconductor substrate 10, and an annealing process is performed, thereby forming the lightly doped region 112 (S113). The ion implantation is performed using, for example, a photoresist as a mask.

After forming the lightly doped region 112, the first drain region 101, the source region 111, the back-gate region 113, and the high-concentration impurity region 114 are formed (S114). Accordingly, the semiconductor device 1 illustrated in FIG. 1 can be manufactured. These regions are formed by implanting ions having the first conductivity type, which is p-type, and ions having the second conductivity type, which is n-type, into the second semiconductor layer 14 from the upper surface 11 of the semiconductor substrate 10 and performing an annealing process. The ion implantation is performed using, for example, a photoresist as a mask. An order of implanting the ions having p-type and the ions having n-type is not limited.

Next, a method of forming the field-plate electrode 35 illustrated in FIG. 11 will be described. After manufacturing the semiconductor device 1 illustrated in FIG. 1, as illustrated in FIG. 25, the insulating layer 34, the sidewall spacer 37, and the field-plate electrode 35 are formed so as to overlap portions of the first insulating region 21 and the gate electrode 31.

First, a material constituting the sidewall spacer 37 is deposited on the upper surface 11 of the semiconductor substrate 10 by, for example, chemical vapor deposition (CVD). The sidewall spacer 37 is formed by etching back the deposited material.

Next, a material constituting the insulating layer 34 is deposited on the upper surface 11 of the semiconductor substrate 10 by CVD. The material constituting the insulating layer 34 is deposited so as to cover the gate electrode 31.

Next, a material constituting the field-plate electrode 35 is deposited on the insulating layer 34 by, for example, CVD or Physical Vapor Deposition (PVD). Next, the material constituting the field-plate electrode 35 is patterned by dry etching using a photoresist formed by photolithography, thereby forming the field-plate electrode 35. Next, the material constituting the insulating layer 34 is patterned by dry etching using a photoresist formed by photolithography, thereby forming the insulating layer 34.

After forming the insulating layer 34 and the field-plate electrode 35, an interlayer insulating film 24 is formed on the upper surface 11 of the semiconductor substrate 10 (S115). The interlayer insulating film 24 is formed by depositing a material constituting the interlayer insulating film 24 by, for example, CVD. Accordingly, the semiconductor device 1 having the field-plate electrode 35 illustrated in FIG. 11 can be manufactured.

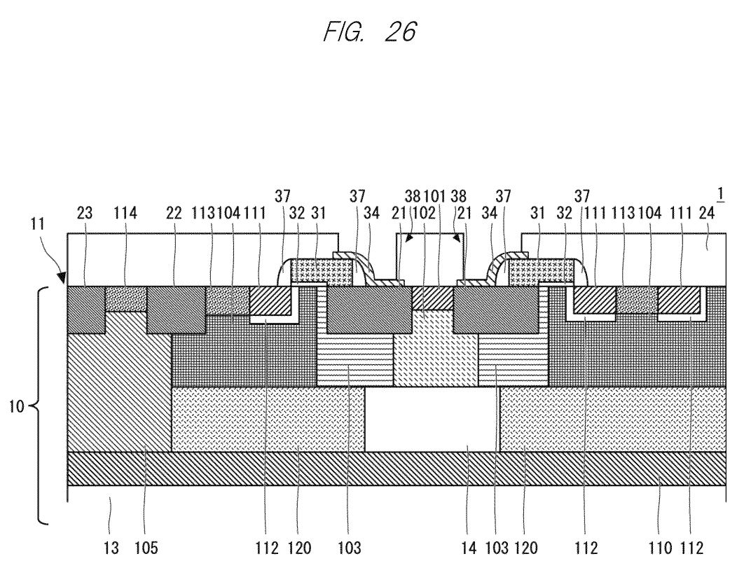

Next, a method of forming the contact field-plate electrode 36 illustrated in FIG. 13 will be described. After manufacturing the semiconductor device 1 illustrated in FIG. 1, as illustrated in FIG. 26, the sidewall spacer 37, the insulating layer 34, and the interlayer insulating film 24 are formed on the upper surface 11 of the semiconductor substrate 10. Thereafter, a through-hole 38 located on the first insulating region 21 is formed in the interlayer insulating film 24.

First, a material constituting the sidewall spacer 37 is deposited on the upper surface 11 of the semiconductor substrate 10 by, for example, CVD. The sidewall spacer 37 is formed by etching back the deposited material.

The insulating layer 34 and the interlayer insulating film 24 are formed by depositing a material constituting the insulating layer 34 and a material constituting the interlayer insulating film 24 by, for example, CVD. The through-hole 38 is formed by patterning the interlayer insulating film 24 by dry etching using a photoresist formed by photolithography.

After forming the interlayer insulating film 24 and the through-hole 38, the contact field-plate electrode 36 is formed in the through-hole 38 (S115). Accordingly, the semiconductor device 1 having the contact field-plate electrode 36 illustrated in FIG. 13 can be manufactured.

Although the inventions made by the present inventors have been specifically described based on the embodiments above, it goes without saying that the present disclosure is not limited to the embodiments already described, and various modifications may be made without departing from the scope of the gist thereof.

What is claimed is:

1. A semiconductor device comprising:
a semiconductor substrate having an upper surface;
a first semiconductor layer formed in the semiconductor substrate;
a first buried region formed in the first semiconductor layer;
a second semiconductor layer formed on the first semiconductor layer;
a drain region formed in the second semiconductor layer and disposed at the upper surface of the semiconductor substrate;
a drift region formed in the second semiconductor layer and disposed so as to surround the drain region in plan view;
a source region formed in the second semiconductor layer, disposed at the upper surface of the semiconductor substrate, and disposed apart from the drain region;
a body region formed in the second semiconductor layer and disposed so as to surround the source region in plan view;
a back-gate region formed in the body region and disposed at the upper surface of the semiconductor substrate;
a gate electrode formed on the upper surface of the semiconductor substrate so as to face the drift region and the body region via a gate insulating film; and
a second buried region formed in the second semiconductor layer and disposed between the first buried region and the body region,
wherein a side surface of the second buried region is located between the gate electrode and the drain region in plan view,
wherein each of the drift region and the body region is located over the second buried region,
wherein each of the semiconductor substrate, the first semiconductor layer, the second semiconductor layer, the drain region, the source region, and the drift region has a first conductivity type,
wherein each of the first buried region, the second buried region, the body region, and the back-gate region has a second conductivity type opposite to the first conductivity type, and
wherein the second buried region is connected to the body region.

2. The semiconductor device according to claim 1,
wherein the drain region includes a first drain region and a second drain region,
wherein the second drain region is disposed under the first drain region, and
wherein an impurity concentration of the second drain region is lower than an impurity concentration of the first drain region.

3. The semiconductor device according to claim 1,
wherein the second buried region is disposed apart from the drain region via the second semiconductor layer.

4. The semiconductor device according to claim 1,
wherein the second buried region surrounds the drain region in plan view.

5. The semiconductor device according to claim 1, further comprising:
a first insulating region formed in the drift region and surrounding the drain region in plan view,
wherein the gate electrode includes a first offset region overlapping the first insulating region in plan view,
wherein the second buried region includes a second offset region overlapping the first insulating region in plan view, and
wherein, in a direction from the source region toward the drain region, a length of the first offset region differs from a length of the second offset region.

6. The semiconductor device according to claim 5,
wherein the length of the first offset region is smaller than the length of the second offset region.

7. The semiconductor device according to claim 1,
wherein a material of the gate electrode is metal or conductive polysilicon.

8. The semiconductor device according to claim 1, further comprising:
a sinker region formed in the second semiconductor layer, the sinker region surrounding the drain region, the drift region, the gate electrode, the source region, the body region, and the second buried region, the sinker region having the second conductivity type,
wherein the sinker region is short-circuited to the first buried region.

9. The semiconductor device according to claim 8,
wherein the second buried region is in contact with the first buried region, and
wherein the second buried region is electrically connected to the sinker region via the first buried region.

10. The semiconductor device according to claim 8,
wherein the second buried region is disposed apart from the first buried region and the sinker region via the second semiconductor layer.

11. The semiconductor device according to claim 8,
wherein the second buried region is disposed apart from the first buried region and the sinker region via a semiconductor region having the first conductivity type, and
wherein an impurity concentration of the semiconductor region is higher than an impurity concentration of the second semiconductor layer.

12. The semiconductor device according to claim 8, further comprising:
a shared contact plug disposed on the back-gate region and on the sinker region,
wherein the shared contact plug short-circuits the source region and the sinker region.

13. The semiconductor device according to claim 5, further comprising:
a field-plate electrode formed on the first insulating region and having a portion overlapping the gate electrode in plan view; and
an interlayer insulating film formed on the semiconductor substrate so as to cover the gate electrode and the field-plate electrode.

14. The semiconductor device according to claim 5, further comprising:
an interlayer insulating film formed on the semiconductor substrate;
a through-hole formed in the interlayer insulating film and located on the first insulating region; and
a contact field-plate electrode formed in the through-hole.
